(19) United States
(12) Patent Application Publication
(10) Pub. No.: US 2022/0393095 A1
(43) Pub. Date: Dec. 8, 2022

(54) Electromechanical Transducer Mount

(71) Applicant: Ultraleap Limited, Bristol (GB)

(72) Inventors: Jamie Chilles, Bristol (GB); Rachael McPhillips, Bath (GB); Carl Withers, Porth (GB); Joe White, Bristol (GB)

(21) Appl. No.: 17/804,998

(22) Filed: Jun. 1, 2022

Related U.S. Application Data
(60) Provisional application No. 63/196,219, filed on Jun. 2, 2021.

(51) Int. Cl. H01L 41/09; H01L 41/053

(52) U.S. Cl. CPC H01L 41/09; H01L 41/053

(57) ABSTRACT

Described herein is mechanically decoupling of an electromechanical transducer from a common substrate, enabling multiple transducers to be surface mounted to a common substrate such as a printed circuit board (PCB) without experiencing mechanical cross-coupling. The decoupling of the transducer from the substrate enables the transducers to be attached without reducing the efficiency of acoustic transduction. The design of the mount enables it to be assembled in an automated manner with pick and place tools.

### PRIOR APPLICATIONS

This application claims the benefit of U.S. Provisional Application Ser. No. 63/196,219, filed on Jun. 2, 2021. This application is incorporated by reference in their entirety.

### FIELD OF THE DISCLOSURE

The present disclosure relates generally to improved structures for electromechanical transducer mounts designed for use in haptic systems.

### BACKGROUND

A mid-air haptic feedback system creates tactile sensations in the air. One way to create mid-air haptic feedback is using ultrasound. A phased array of ultrasonic transducers is used to exert an acoustic radiation force on a target. This continuous distribution of sound energy, which will be referred to herein as an “acoustic field”, is useful for a range of applications, including haptic feedback.

It is known to control an acoustic field by defining one or more control points in a space within which the acoustic field may exist. Each control point is assigned an amplitude value equating to a desired amplitude of the acoustic field at the control point. Transducers are then controlled to create an acoustic field exhibiting the desired amplitude at each of the control points.

Tactile sensations on human skin can be created by using a phased array of ultrasound transducers to exert an acoustic radiation force on a target in mid-air. Ultrasound waves are transmitted by the transducers, with the phase emitted by each transducer adjusted such that the waves arrive concurrently at the target point in order to maximize the acoustic radiation force exerted.

By defining one or more control points in space, the acoustic field can be controlled. Each point can be assigned a value equating to a desired amplitude at the control point. A physical set of transducers can then be controlled to create an acoustic field exhibiting the desired amplitude at the control points.

The problem to be addressed herein is the production of an electromechanical structure that can surface mount an acoustic transducer to an array board in a way that mechanically decouples the transducer from the array board, without reducing the magnitude of the pressure generated by the transducer. In addition to the acoustical requirements, the transducer mount must also provide the signal and ground paths to an array board to allow the transducer to be electrically excited. The mount design presented herein achieves the specified requirements in a form factor that enables the design to be produced using automatable manufacturing tools, that are scalable for high volumes.

Mechanical cross-coupling is a problem that can occur whenever there are multiple vibrating devices attached to or embedded within a common substrate layer (such as an array board). The coupling occurs due to the propagation of elastic waves through the substrate. See Certon, D., Felix, N., Lacaze, E., Teston, F., & Patat, F. (2001). Investigation of cross-coupling in 1-3 piezocomposite arrays. IEEE transactions on ultrasonics, ferroelectrics, and frequency wntrol, 48(1), 85-92 (“Certon 2001”); Certon, D., Felix, N., Hue, P. T. H., Patat, F., & Lethiecq, M. (1999, October). Evaluation of laser probe performances for measuring cross-coupling in 1-3 piezocomposite arrays, 1999 IEEE Ultrasonics Symposium. Proceedings. International Symposium (Cat. No. 99CH37027) (Vol. 2, pp. 1091-1094). IEEE (“Certon 1999”).

The effect of these waves is to couple the displacements of one device to another. This has the effect of defocusing the acoustic field emitted by the array by altering the phase delays applied to devices, and reducing the acoustic energy transmitted into the desired medium. Certon 2001. The use of phased arrays has been established for many years in the fields of medical imaging and non-destructive testing of engineering structures. There have been many solutions developed to reduce mechanical-cross talk between devices, however, each of these solutions has drawbacks which prevent them solving all of the problems outlined above.

One of the most common approaches is to bond a backing layer to the back of the transducer that dampens the transmission of vibrations between the elements. Often the layer is designed such that the impedance matches that of the radiating element. If the impedance of the backing layer matches the radiating element, then there is no reflection at the boundary and the ultrasound is not reflected back. This design reduces coupling and increases the bandwidth of devices; however, an adverse side effect of this design is that it reduces the efficiency of the transmission of acoustic energy into the medium of inspection/interaction. See DeSilets, C. S. (1978). Transducer arrays suitable for acoustic imaging (No. GL-2833). STANFORD UNIV CA EDWARD L GINZTON LAB OF PHYSICS: https://radiopaedia.org/articles/physical-principles-of-ultrasound-1?lang=gb (accessed May 29, 2022).

In mid-air haptic applications, where there is a significant mismatch in impedance between the transducer and air, and which require the generation of high sound pressures (>=155 dB) any further reductions in transmission efficiency are unacceptable, rendering this solution impractical from a power consumption perspective.

Another approach often used is to have the transducers constructed such that they are ‘air-backed’. This method of construction lends itself to designs that are machined from a single piece of PZT such as piezocomposite designs where a polymer is used to fill in cutaway sections. See Waiter, S., Nieweglowski, K., Rebenklau, L., Wolter, K. J., Lamek, B., Schubert, F., & Meyendorf, N. (2008, May). Manufacturing and electrical interconnection of piezoelectric 1-3 composite materials for phased array ultrasonic transducers, 2008 31 st International Spring Seminar on Electronics Technology (pp. 255-260). IEEE (“Walter”).

The thickness mode vibration of the piezoelectric elements and the reduced thickness of the front plate limit the coupling in this configuration. The air backed design maximizes the energy transmitted by the array. See Walter; Patricio Rodrigues, E., Francisco de Oliveira, T., Yassunori Matuda, M., & Buiochi, F. (2019, September). Design and Construction of a 2-D Phased Array Ultrasonic Transducer for Coupling in Water, INTER-NOISE and NOISE-CON Congress and Conference Proceedings (Vol. 259, No. 4, pp. 5720-5731). Institute of Noise Control Engineering.

This method is not practical in the case of surface mounted components, as the transducers must be physically supported by a layer that sits between the vibrating elements of the transducer and array substrate. It is also worth noting that most air-coupled transducers do not operate in the thickness mode due to the reduced volumetric displacement in comparison to bending mode devices.

A novel approach is to use so called ‘stop band’ layers. In these designs the substrate of the array is designed such that tuned mechanical resonators are on its backside. These resonators couple to the elastic waves generated by the transducers in the substrate, and reduce the cross-coupling by attenuating the elastic waves in the backing layer itself. See Henneberg, J., Gerlach, A., Storck, H., Cebulla, H., & Marburg, S. (2018). Reducing mechanical cross-coupling in phased array transducers using stop band material as backing. Journal of Sound and Vibration, 424, 352-364.

While this represents an ingenious solution, it places tight requirements on the array substrate and may limit the application of this design in a practical systems where electrical components are bonded to the substrate (often made from PCB), and the substrate contained within a structure that has its own bespoke requirements dictated by an application. A further drawback of this approach is that the energy is still propagated from the transducers into the substrate and lost within the substrate rather than being transmitted as acoustic energy into the desired medium.

Another approach is to use signal processing techniques to compensate for the existence of cross-coupling. This method has been demonstrated to work experimentally, however, such techniques require accurate characterization of the array and increase the complexity involved in dynamic solving. See Bybi, A., Grondel, S., Mzerd, A., Granger, C., Garoum, M., & Assaad, J. (2019). Investigation of cross-coupling in piezoelectric transducer arrays and correction. International Journal of Engineering and Technology Innovation, 9(4), 287.

The second point is particularly damaging to applications such as mid-air haptics where the array has to dynamically solve the location of the focus point, and would require an unfeasibly large amount of experimental data to look up suitable compensated phase delays.

The design submitted in this application is an example of a passive electromechanical structure which in this case is comprised of wire bonds and deposited compliant pillars. Mechanically this appears as a low impedance interface that sits between the vibrating transducer and array substrate (often a PCB). The low mechanical impedance of the mount results in high efficiency of transducer output, and a part that is mechanically decoupled from the array board, and hence removes cross-coupling between adjacent transducing elements. A notable further benefit of this design is that it achieves this behavior with materials and processes typically used in high volume manufacture, and can be assembled using standard pick and place tools. The produced component is able to either support or encase the transducer as a surface mountable component. Due to being decoupled from the array substrate, transducers with this mount are almost insensitive to the components and materials present on the array board. Whilst the mount has been developed to decouple ultrasonic transducers, the design could be applied to decouple the vibrations between any arbitrary electromechanical components bonded to a common substrate.

### SUMMARY

The disclosure described herein mechanically decouples an electromechanical transducer from a common substrate, enabling multiple transducers to be surface mounted to a common substrate such as a printed circuit board (PCB) without experiencing mechanical cross-coupling. The decoupling of the transducer from the substrate enables the transducers to be attached without reducing the efficiency of acoustic transduction. The design of the mount enables it to be assembled in an automated manner with pick and place tools. This disclosure describes how the presented design functions, as well as a manufacturing process by which the part can be assembled in an automated manner. The design presented herein is optimized to decouple an ultrasonic transducer, however, the design could be adapted to decouple the vibrations of any component bonded to a common substrate layer that requires electrical excitation.

### BRIEF DESCRIPTION OF THE DRAWINGS

The accompanying figures, where like reference numerals refer to identical or functionally similar elements throughout the separate views, together with the detailed description below, are incorporated in and form part of the specification, serve to further illustrate embodiments of concepts that include the claimed invention and explain various principles and advantages of those embodiments.

FIGS. 1A, 1B, and 1C show an exemplary transducer mount.

FIG. 2 shows a diagram with a boundary with specific impedance between transducers and a printed circuit (PCB) substrate.

FIG. 3 plots the specific impedance of the mount versus the magnitude of the cross-coupling.

FIGS. 4A and 4B show a simulation having time series responses with high and low impedance interface between transducers and a substrate.

FIG. 5 shows radiated acoustic power at increasing mount impedances.

FIGS. 6 and 7 show laser Doppler vibrometer data having respective cross coupling of −40 dB and −11 dB using the transducer mount shown in FIG. 1.

FIG. 8 is a tape frame of singulated PCB substrates.

FIG. 9 shows an example of wire bonds on PCB pads.

FIG. 10 shows silver conductive epoxy bead on the peak of wire bond pairs.

FIGS. 11A and 11B show wafflepacks placed onto wire bond loops following silicone dispense.

FIGS. 12A, 12B, 12C, 12D show a series of wire bond configurations.

FIGS. 13A, 13B, and 13C shows a transducer mount designed to conform with a molded surface mount package.

FIG. 14 shows a side view of a complete package assembly.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

Acoustic transducers are resonant devices, the resonance is dictated by the mass, compliance and damping present in the transducer. When used in an array form, each device is actuated individually such that the generated pressures constructively interact at a desired location to create locally high regions of acoustic pressure. Throughout this application, the term “harmonic” will be used to refer to a dynamically varying quantity with a magnitude and phase oscillating at a single frequency. Transducers generate the highest pressures when the frequency of the harmonic voltage used to excite the transducer coincides with the transducer's resonant frequency. This requires an array to consist of multiple transducers with similar resonant frequencies, and ensures that all of the devices are driven sufficiently close to their resonant frequencies that the acoustic pressure generated 1w the array is maximized. The closely matched resonances of the transducers results in excessive cross-coupling and a degradation in array performance when the transducers are directly bonded to a common substrate.

The transducer mount design presented here removes cross-coupling between transducers with similar resonant frequencies by acting as a low impedance layer between the transducer and substrate. The design achieves this in a manner that maximizes the acoustic energy transmission, without the need for backing layers to attenuate the mechanical energy (which would result in inefficiency). The presented design is compatible with pick and place tools which enables the part to be assembled in high volume and at low cost. The produced part is compatible with commercially desirable surface mount attach processes such as reflow soldering, which allows arrays of transducers to be produced in high volumes with manufacturing processes commonly used in the electronics and semi-conductor industries.

### I. TRANSDUCER MOUNT DESIGN

The invention presented herein consists of three main components: A carrier which routes the electrical connections from a common substrate layer to the transducer (for example a singulated PCB, wire bonds made from a conductive material which connect the conductive pads on the carrier to the mounted component (in this case an ultrasonic transducer) and compliant pillars made from a low modulus material which support the mounted component. This assembly will hereafter be referred to as the ‘transducer mount’. The function of the transducer mount is to provide a low impedance interface between the transducer and array board such that mechanical vibrations between neighboring devices are decoupled, to maximize the acoustic energy transmitted by the transducer into the desired medium, and to provide electrical connections to the transducer.

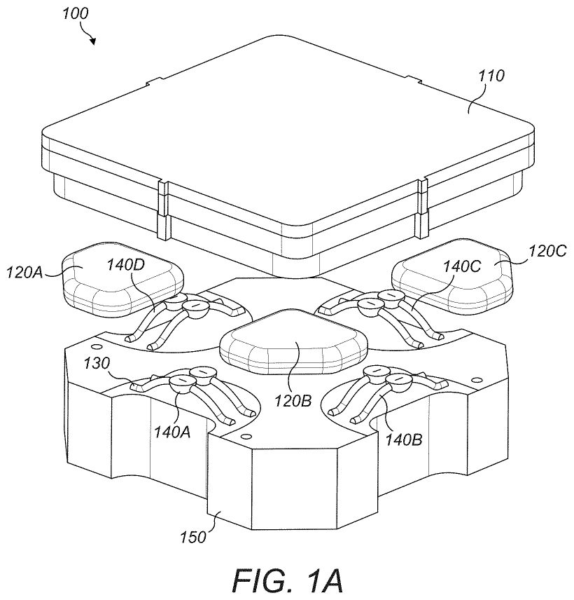

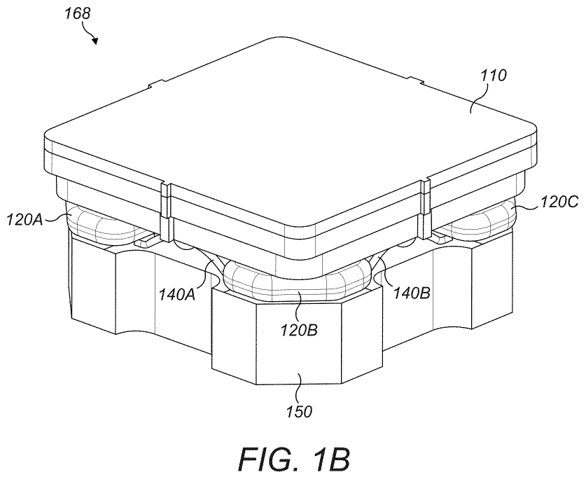

Turning to FIGS. 1A, 1B, and 1C, shown are various views of an exemplary transducer mount.

FIG. 1A shows an exploded view where the transducer mount 100 has a transducer 110, pillars of compliant material 120A, 120B, 120C, conduct adhesive 130, wire bonds 140A, 140B, 1400, 140D, and a printed circuit board 150.

FIG. 1B shows a mounted transducer assembly where the transducer mount 168 has a transducer 110, pillars of compliant material 120A, 120B, 120C, conduct adhesive 130, wire bonds 140A, 140B, and a printed circuit board 150.

FIG. 1C shows a side view of a mounted transducer assembly where the transducer mount 175 has a transducer 110, pillars of compliant material 120A, 120B, conduct adhesive 130, wire bond 140A, and a printed circuit board 150.

This assembly allows multiple transducers to be surface mounted to a common substrate without inducing mechanical cross-coupling between adjacent elements, and for the efficiency of acoustic energy generated by the transducer to be maximized.

The mechanical properties and geometry of the components are carefully designed so as to maximize the mechanical compliance and minimize the mechanical impedance of the transducer mount.

Theses designs incorporate Equations 1 to 3, which are cited from the work of Beranek, L., & Mellow, T. (2019). Acoustics: Sound Fields, Transducers and Vibration. Academic Press. Equation 1 can be used to calculate the mechanical impedance. The mechanical impedance Zₘ is defined as the ratio of the harmonic force \tilde{f} to harmonic velocity ũ. The mechanical impedance of a transducer mount of compliance C_{M} excited by a harmonic force of angular velocity ω can be calculated using Equation 2. The mechanical impedance Zₘ can then be converted to a specific impedance Zₛ by dividing by the area over which the harmonic force is applied, as shown in Equation 3. Equations 1 to 3 enable calculation of the impedance of a mount by modelling it as a simple lumped element mechanical compliance. It can be seen by inspecting Equations 1 to 3 that for the mount design to behave as a low impedance interface its mechanical compliance should be maximized. In the presented design this is achieved by the selection of an appropriate geometry for the conductors and low modulus of the pillars.

$${Z}_{m} = \frac{\tilde{f}}{\tilde{u}} \qquad Eq . 1$$

$${Z}_{m} = \frac{1}{j ω {C}_{M}} \qquad Eq . 2$$

$${Z}_{s} = \frac{\tilde{p}}{\tilde{u}} = \frac{{Z}_{m}}{A} \qquad Eq . 3$$

The inequality shown in Equation 4 describes the general condition that the magnitude of the specific impedance |Zₛ| of the transducer mount must be broadly less than the magnitude of critical impedance |Z_{c}| to limit cross-coupling and maximise power transmission. Creation of a mount where |Zₛ|>|Z_{c}|, would reduce the efficiency of transduction and increases the mechanical cross-coupling between transducers.

|Zₛ|≤|Z_{c}| Eq. 4

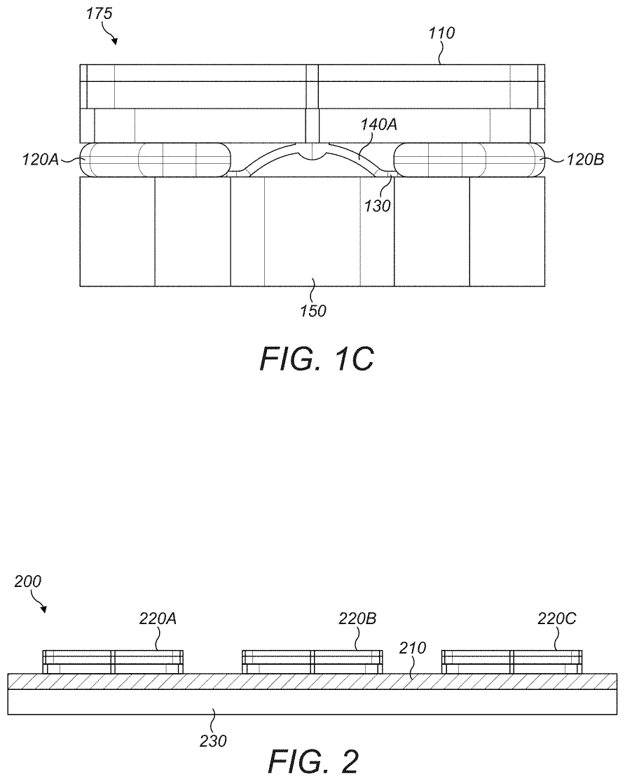

Turning to FIG. 2, shown is a diagram 200 with a boundary 210 with specific impedance Zₛ between the transducers 220A, 220B, 220C and a printed circuit (PCB) substrate 230. In this example, both experimental and simulated data is presented for the case where 60 kHz transducers made from relatively high impedance material(s) (>15 MRayls) are attached to an FR4-PCB with a transducer mount of varying impedance |Zₛ|.

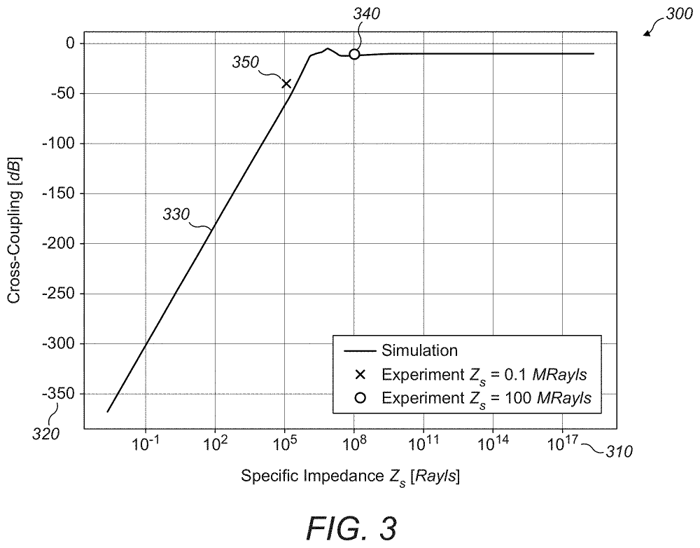

Turning to FIG. 3, shown is plot 300 showing the specific impedance Zₛ of the mount in Rayls 310 versus the magnitude of the cross-coupling in dB 320. The black line 330 shows the simulated cross-coupling between 60 kHz, transducers made from materials with a characteristic impedance >15 MRayls surface mounted to a PCB with a transducer mount of impedance Zₛ. Experimental measurements are shown as crosses for mount impedances of 0.1 MRayls 350 and 100 MRayls 340.

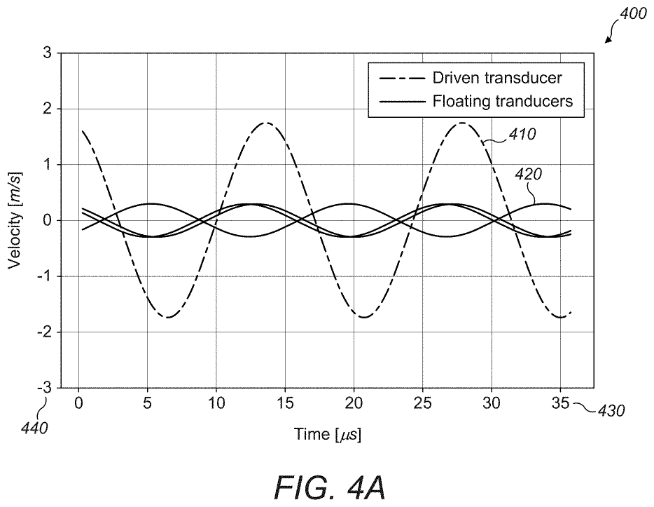

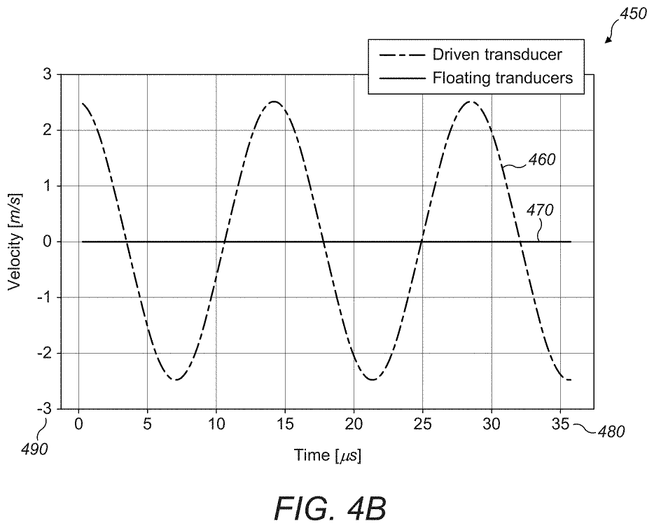

FIGS. 4A and 4B demonstrate the benefits of a low impedance mount, and its ability to decouple the motion of individual transducers. These are simulations showing time series responses with high and low impedance interface between the transducers and the substrate. The driven transducer has a harmonic voltage applied to it, while the floating devices have no external voltage applied to them.

Turning to FIG. 4A, shown is a plot 400 having an x-axis 430 showing time in μs and the y-axis 440 showing velocity in m/s. Shown are plots of a driven transducer 410 and a floating transducer 420 at a velocity data time series with an impedance boundary of Zₛ=2×10¹⁹ Rayls. This demonstrates the removal of any significant cross-coupling between transducers when the inequality |Zₛ|≤|Z_{c}| is met.

Turning to FIG. 4B, shown is a plot 450 having an x-axis 480 showing time in μs and the y-axis 490 showing velocity in m/s. Shown are plots of a driven transducer 40 and a floating transducer 420 at a simulated velocity time series with a boundary impedance of Zₛ=2.21 Rayls. This demonstrates how cross-coupling is reduced to an acceptable level when the inequality is obeyed (i.e. when |Zₛ|<|Z_{c}|). The critical impedance will vary for a given array board and transducer combination.

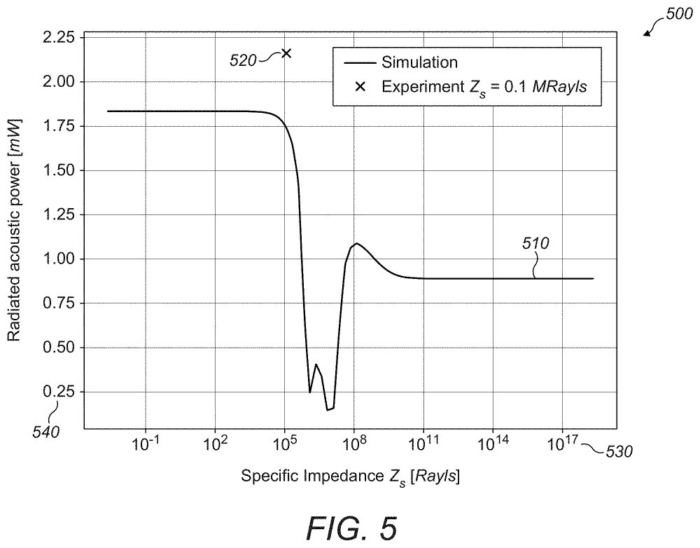

Turning to FIG. 5, shown is a plot 500 with an x-axis of specific impedance Zₛ in Rayls 530 and a y-axis of radiated acoustic power in mW 540. In this example a mount impedance ≤0.1 MRayls is required to decouple the transducers and maximise the radiated acoustic power. The black line 510 shows the simulated radiated acoustic power by a 60 kHz transducer made from materials with a characteristic impedance >15 MRayls surface mounted to a PCB with a transducer mount of impedance Zₛ. Experimental measurement shown as a cross 520 for a mount impedance of 0.1 MRayls.

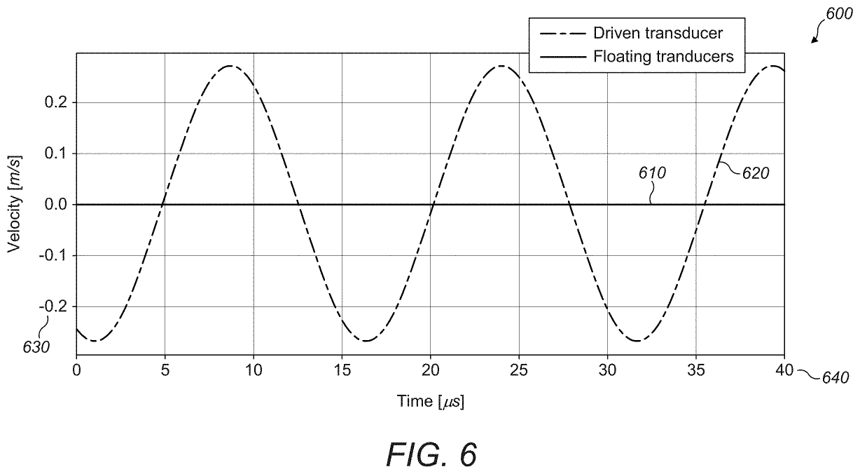

Turning to FIG. 6, shown is a plot 600 having an x-axis 640 showing time in μs and the y-axis 630 showing velocity in m/s. The driven transducers 620 and floating transducers 610 are shown. The data originates from a laser Doppler vibrometer data showing cross coupling of −40 dB with 60 kHz transducers made from materials with characteristic impedance >15 MRayls surface mounted to a PCB using the transducer mount shown in FIG. 1. Here, the estimated mount impedance is |Zₛ|=0.1 MRayls where |Zₛ|≤|Z_{c}|.

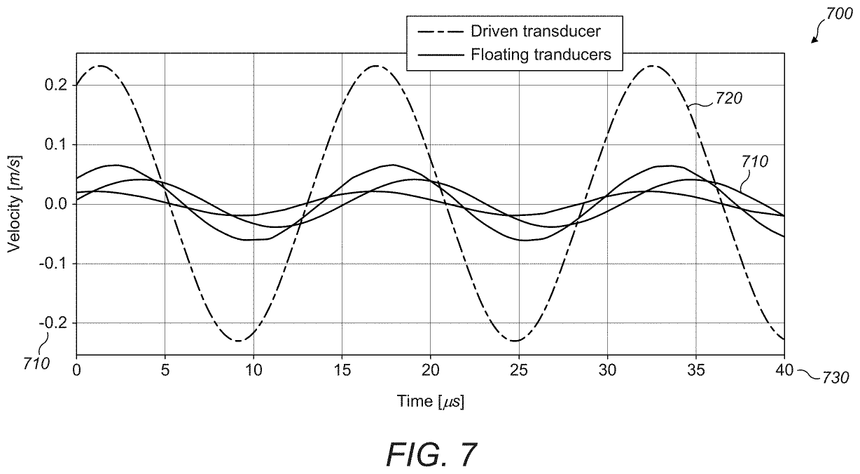

Turning to FIG. 7, shown is a plot 700 having an x-axis 730 showing time in μs and the y-axis 710 showing velocity m/s. The driven transducers 720 and floating transducers 710 are shown. The data originates from a laser Doppler vibrometer data showing cross coupling of −11 dB with 60 kHz transducers made from materials with characteristic impedance >15 MRayls mounted to a PCB using conductive epoxy. Here, the estimated mount impedance is |Zₛ|=100 MRayls, which exceeds the critical impedance where |Zₛ|≥|Z_{c}|.

Table 1 shows the characteristic impedance of a number of materials relevant to ultrasonic transducers. Table 2 shows a series of critical transducer mount impedances required to decouple transducers operating at 40 kHz, 60 kHz and 100 kHz made from a relatively high impedance material(s) (>15 MRayls) bonded to a FR4-PCB. Notice that all of the critical impedances are lower than the values shown in Table 1, and that the critical transducer mount impedance is relatively low in magnitude.

TABLE 1

| | | Speed of | Characteristic |
|---|---|---|---|
| | Density | sound | Impedance |
| | Unit | | |
| Material | kg/m³ | ms⁻¹ | MRayls |
| Steel | 7700 | 6100 | 47 |
| Aluminum | 2690 | 6420 | 17.3 |
| FR4-PCB] | 1850 | 3602 | 6.6 |
| PZT-5 | 7900 | 4390 | 34.7 |
| Epoxy | 2554 | 1170 | 3 |
| ABS | 2250 | 1050 | 2.4 |

TABLE 2

| | | | 40 | 60 | 100 |
|---|---|---|---|---|---|
| Parameter | Symbol | Units | kHz | kHz | kHz |
| Critical Specific | \|Z_{c}\| | MRayls | 0.05 | 0.1 | 0.5 |
| Impedance | | | | | |
| Critical mechanical | \|C_{mc}\| | μm/N | 2 | 0.8 | 0.9 |
| compliance | | | | | |

Equation 5 shows how the mechanical compliance C_{M} can be calculated from the mechanical impedance Zₘ, and angular frequency ω. The inequality in Equation 6 can then be formed by inputting the critical specific impedance Z_{C} of the transducer mount into Equation 5. The resulting inequality identifies that the transducer mount must be sufficiently complaint so as to reduce cross-coupling and maximize transduction efficiency. Table 1 shows the critical mechanical compliance values for the example transducer configurations.

$${C}_{M} = \frac{1}{j ω {Z}_{m}} \qquad Eq . 5$$

$${C}_{M} \geq \frac{1}{j ω {Z}_{C}} \qquad Eq . 6$$

The previous section describes how the transducer mount achieves the acoustical requirements of reducing the mechanical cross-coupling and maximizing the radiated acoustic power. In addition to the acoustical requirements, the transducer mount must connect the transducer to the electrical connections in the substrate layer. FIG. 1 shows an example of a configuration that achieves this using a combination of a singulated PCB, wire bonds and conductive epoxy. It should be noted that due to the impedance of the pillars of compliant material and wire bonds, simulation of the PCB is a feature of the example, but is not necessary to realize the decoupling aspect of the invention. In this specific configuration wire bonds are formed on each of the PCB's pads, the apex of each wire bond is bonded with conductive adhesive to the underside of the transducer which has its own ground and signal connections. The singulated PCB at the base of the transducer is then attached to the ground and signal connections of the substrate layer, which allows the transducer to be excited by electrical hardware connected to the substrate layer. The PCB acts as the interface between the transducer and other electrical hardware. The transducer mount is not limited to using a PCB as the carrier, the mount could be supported by any part with separate ground and signal connections.

The example of a transducer mount designed to decouple 60 kHz transducers surface mounted to a PCB is shown in FIGS. 1A, 1B, and 1C. This specific configuration was manufactured and demonstrated to meet the design requirements experimentally. The geometrical parameters used in this specific configuration are shown in Table 3 under the column heading “60 kHz transducer mount”. These properties are examples of those which could be used to construct a surface mount compatible transducer mount. Table 3A shows the material properties of each component used to construct this demonstrator; the demonstrator has an estimated impedance of 0.1 MRayls.

Table 3 further shows examples of the geometrical parameters used to construct a transducer mount which decouples transducers attached to a PCB operating at 40, 60 and 100 kHz. The transducers in this example are made from a relatively high impedance material (>15 MRayls), each has a different operating frequency and is bonded to a FR4-PCB,

TABLE 3

| | 40 kHz | | 60 kHz | | 100 kHz | |
|---|---|---|---|---|---|---|
| Geometrical | transducer | | transducer | | transducer | |
| parameter | mount | | mount | | mount | |
| Transducer mount height | 1.5 | mm | 0.6 | mm | 0.15 | mm |
| Wire bond loop width | 2.0 | mm | 2.0 | mm | 0.5 | mm |
| Total number of wire | 2 | | 8 | | 8 | |
| bonds | | | | | | |
| Total cross sectional area | 10 | mm² | 12 | mm² | 10 | mm² |
| of compliant material | | | | | | |

| Material | Young's Modulus | |
|---|---|---|
| Wire bond | 70 | GPa |
| Conductive adhesive | 4 | GPa |
| Compliant material | 0.0015 | GPa |

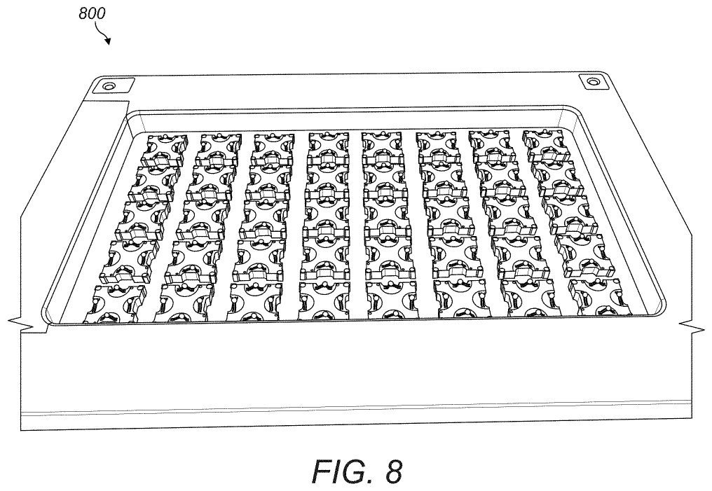

Turning to FIG. 8, shown is a tape frame of singulated PCB substrates 800. FIG. 8 confirms the ability of the transducer mount to decouple the transducer when surface mounted to a PCB. The velocity data recorded with a scanning laser Doppler vibrometer shows that the coupling between the neighboring devices is minimal, and the calculated cross-coupling of −40 dB is sufficiently low to enable the transducers to be used in phased array applications.

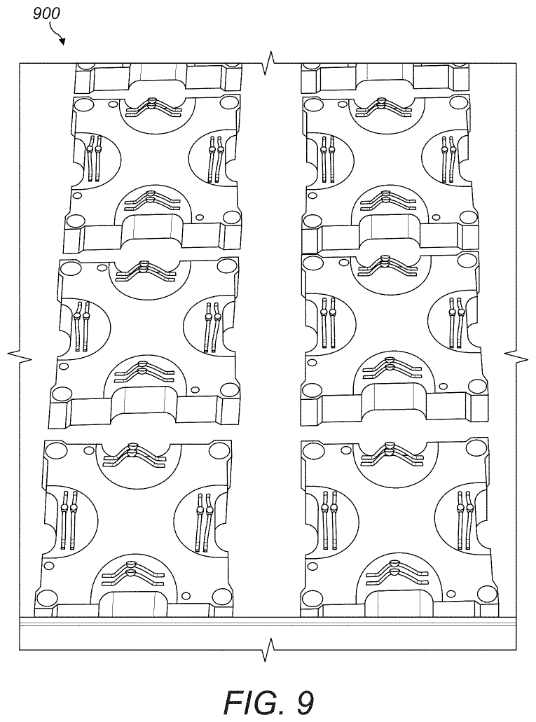

Turning to FIG. 9 shows an example of wire bonds on each PCB pad 900. The laser Doppler vibrometer data shown in FIG. 9 shows the cross-coupling present when the transducers are mounted directly to a PCB using conductive epoxy, rather than a compliant transducer mount. The increased mount impedance of 100 MRayls resulted in the cross-coupling increasing to −11 dB, cross-coupling to this extent would Hake it impractical to use the devices in phased array applications.

The transducer mount acts as a low impedance interface between the transducer and substrate layer. When the specific impedance of the transducer mount meets the inequality shown in Equation 4 the transducers are decoupled from the PCB and efficiency of acoustic transduction is maximized. The critical impedance of the transducer mount varies with transducer and substrate construction; however, the critical impedance will always be lower than the impedance of the transducer (Tables 1 and 2). The results demonstrate that the transducer mount reported in herein is capable of decoupling transducers. This section outlined principle of operation of the transducer mount and provided multiple versions suitable for different applications, the subsequent section will outline how this component could be manufactured in an automated process.

### II. MANUFACTURING PROCESS

This section outlines the manufacturing process of the transducer mount shown in FIG. 1, as an example of a manufacturing process that may be undergone to realize the invention. Alternative designs could be produced by modifications to the components and geometry. At each process step alternative configurations/manufacturing techniques are described which could be used to achieve the same function in a different configuration. This manufacturing process of the mount is designed to be fully automated. The process uses wire bond technology combined with standard pick and place assembly techniques to create a scalable process suitable for high volume production. The manufacturing process steps are outlined below:

1. Singulated PCBs are mounted into a grid pattern for the process of wire bonding (shown in FIG. 8). In the example configuration in FIG. 1 a singulated PCB is used as the carrier, this could be replaced by any structure with routed electrical connections such as, for instance, a molded plastic casing with metallic pads on its underside such as those commonly seen in surface mount packages.

2. Wire bonds are bonded to the tops of the conductive pads of the PCB as shown in FIG. 9, If an alternative carrier to a PCB is used the wire bonds would be formed onto the conductive pads in that form, for example in a molded plastic case the wire bonds would be formed onto the exposed sections of conductor embedded in the molded plastic.

3. Frames of wire bonded PCBs or alternative wire bonded carriers are then transported through a pick and place tool or similar device capable of dispensing conductive adhesive on top of the wire bonds.

For example, turning to FIG. 10, shown is a silver conductive epoxy bead on the peak of the wire bond pairs 1000. An alternative configuration of this part of the process could instead involve a direct wire bond from the electrodes of the carrier to the transducer.

4. A low modulus material is then dispensed along the corners of the PCB. Any material with a sufficiently low modulus so as not to exceed the critical compliance of the mount would be acceptable. In this case the compliant material was dispensed, however, this could be molded to the carrier.

5. The transducer assembly is then placed onto the wire bonds. This can be done individually or from a package such as a waffle pack. The low modulus material forms a mechanical bond to the transducer and holds it in place while the wire bonds between the signal and ground connection of the transducer and the carrier define the height at which it sits.

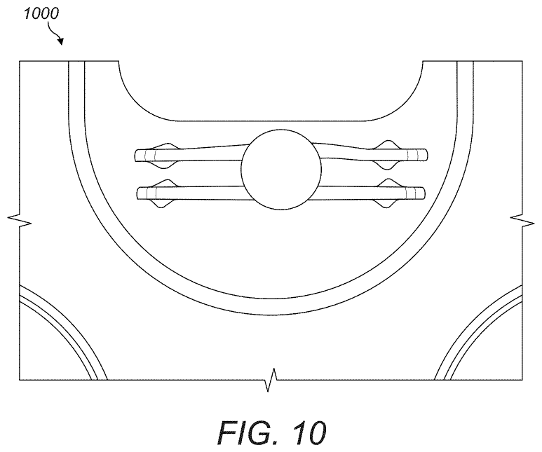

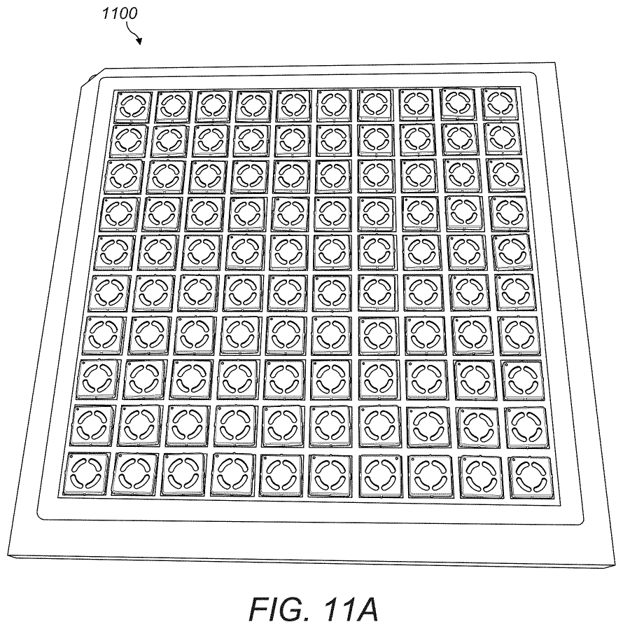

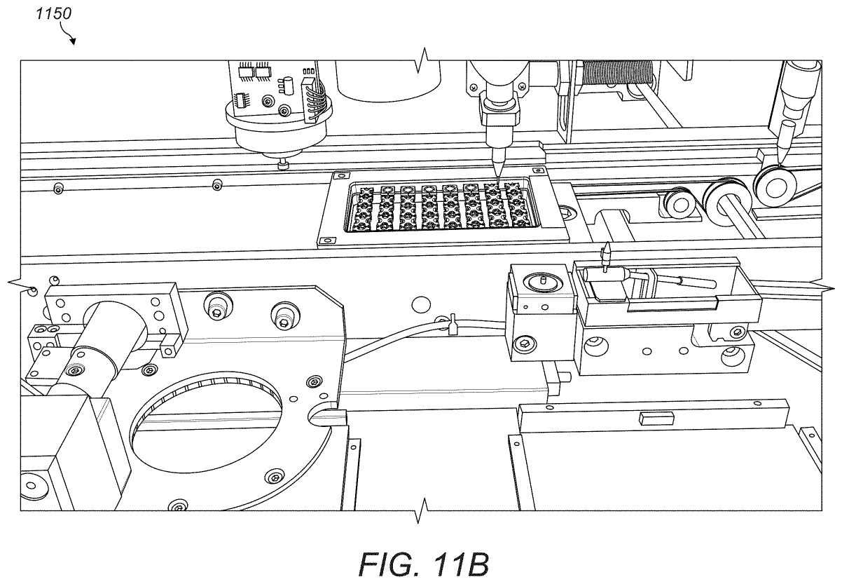

For example, turning to FIG. 11A, shown is a wafflepack of transducers 1100. Turning to FIG. 11B, show in how these are picked from the wafflepacks and placed onto wire bond loops following silicone dispense 1150.

6. Batches of this assembly are then cured at elevated temperature to cure the adhesive and compliant material. Once cured, the finished assembly is ready for test and used in whatever application the user desires; mid-air haptic arrays, ultrasonic range finding or any other application requiring high efficiency electromechanical acoustic transducers. If the wire bonds have been formed directly to the transducer this curing step may not be required.

One of the key features of this manufacturing process is the use of wire bonds. Wire bonding allows for batch production at high volumes, enabling low production costs. The wire bonds have a small footprint, and are therefore a feasible electrical connection method for future smaller versions of the transducer. Wire bonding is a widely adopted manufacturing process in the semi-conductor industry, as such there exist many different tools capable of precise control of the wire form. Precise control of the form enables the height of the transducer to be accurately controlled. Wire bonding is carried out with a low process temperature. This is of interest to allow for flexibility in future design iterations of this product, as the transducers performance may be temperature sensitive, and degraded at excessively high processing temperatures (this is a known limitation of many piezoelectric materials that could present alternatives for use in such a design). In this specific design, a wire thickness of 125 um is used. Tests show this thickness is suitable for mechanical isolation while also having sufficient mechanical strength to withstand a downward force of 7.4 N. This force is well within the limits of what would be required for a pick and place tool when handling the component and placing the transducer onto this mount assembly.

### III. ALTERNATIVE CONFIGURATIONS

The transducer mount shown in FIG. 1 with geometrical and material properties detailed in Tables 2 and 3 represents one possible version of this invention that has been designed for a specific application; decoupling 60 kHz transducers made from a high impedance materials (>15 MRayls) surface mounted to a PCB. This version of the transducer mount has been experimentally validated as being able to decouple the transducers, maximize the radiated acoustic power, and provide the electrical connections to the transducer (shown in FIGS. 5, 6 and 7). There exist a number of possible alternative configurations that could be used to adapt this design for alternative applications. These are described below.

A. Alternative Operating Frequencies

The presented example has been manufactured and tested at 60 kHz. By following the documented process transducers mounts can be redesigned for a range of different operating frequencies. Tables 1 shows the critical impedance for transducers operating at 40 kHz, 60 kHz and 100 kHz. Note that this design is not limited to these frequencies, and these are just relevant examples for resonators operating in air.

B. Reduced Transducer Mount Impedance

The examples of transducer mounts provided herein have been designed for decoupling transducers made from a relatively high impedance material (>15 MRayls). The design is also capable of being adapted to decouple transducers manufactured from lower impedance materials, for example the lower impedance materials in Table 1 (ABS and epoxy). The effect of such material selections on the transducer mount would be to reduce the critical impedance of the transducer mount below which cross-coupling and transduction efficiency is maximized. The critical impedance will need to be lower than the impedance of the transducer.

C. Direct Wire Bond to the Transducer

In the construction shown in FIG. 1 and the described manufacturing process the wire bonds are bonded to the transducer using conductive adhesive. It would be possible to wire bond directly to the PCB and the transducer in a manner that does not require conductive adhesive. This method would remove the need for additional curing steps and has the potential for a lower cost manufacturing process.

D. Alternative Wire Bond Form

The design shown in FIG. 1 uses wire bonds in a loop form, with the loop resembling a semi-circle. This is one possible configuration that could be implemented in the transducer mount. There are a range of potential geometries that could be applied while still achieving the primary goal of the transducer mount, that of providing a low impedance interface for the transducer. Providing the mechanical compliance and specific impedance of the mount component do not exceed the critical value at the operating frequency, any permitted geometry is possible. Table 2 provides examples of the critical compliance and impedances at 40 kHz, 60 kHz, and 100 kHz.

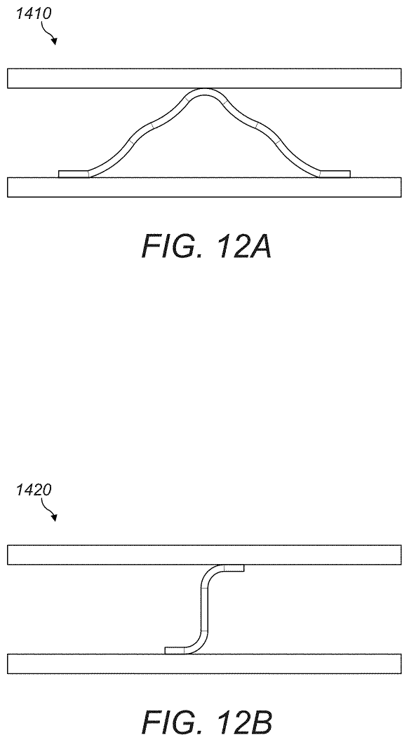

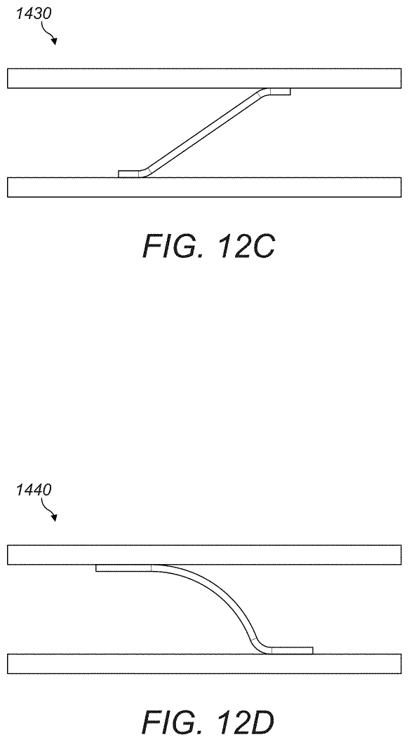

FIGS. 12A, 12B, 12C, and 12D shows some examples of wire bond profiles 1410 1420 1430 1440 that could be applied to the transducer mount. In addition to the geometrical form the wire bonds could be made from a range of different conductors. The tested design was manufactured with aluminum wire bonds; however, the presented design could function with wire bonds made from any conductor. Too, in each configuration the wire could be attached to the conductors in multiple ways; direct wire bonding or attached using conductive adhesive.

E. Alternative Carrier

The transducer design presented in FIG. 1 has been demonstrated to decouple transducers attached to a PCB. The components of the mount responsible for this behavior are the pillars of the compliant material and the wire bonds. The PCB at the base of the transducer mount acts as a carrier and merely supports the other components and routes the electrical connections, this could be for instance replaced with a molded plastic case which has embedded electrical connections such as those typically used to encase surface mount components.

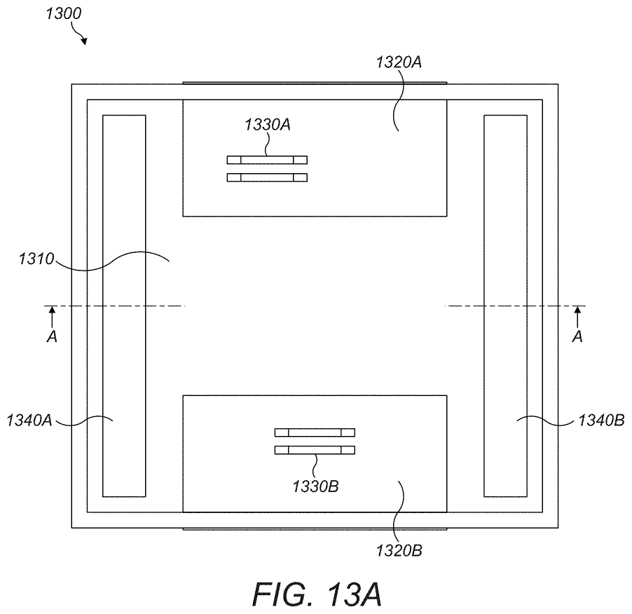

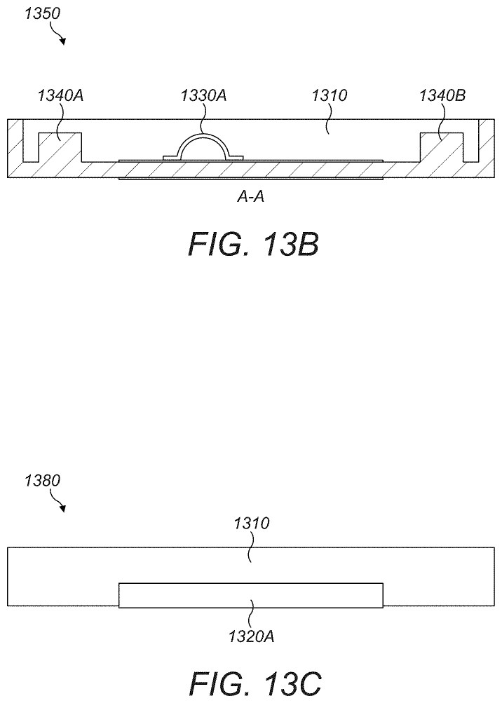

Turning to FIGS. 13A, 13B, 13C, shown are how the transducer mount can be designed to conform with a molded surface mount package using alternative configurations of the transducer mount with the compliant material and wire bonds contained within a moulded surface mount.

FIG. 13A shows an overhead view 1300 with a molded package carrier 1310, conductive pads 1320A 1320B, wire bonds 1330A 1330B and compliant material 1340A 1340B.

FIG. 13B shows a cross section view A-A 1350 based on the A-A in FIG. 13A. Shown are conductive pads 1340A 1340B, a molded package carrier 1310, and wire bonds 1330A,

FIG. 13C shows a side view 1380 with a molded package carrier 1310 and conductive pad 1320A.

F. Alternative Compliant Material

The transducer mourn uses pillars of a compliant material at the corners (FIG. 1) to provide a low impedance interface capable of supporting the transducer. The transducer mount is not limited to this configuration. Any material and geometrical configuration could be used providing that the Young's modulus, cross sectional area and thickness resulted in the impedance of the transducer mount not exceeding its critical value for the given transducer construction (see examples shown in Table 1). In certain configurations the compliant material could also function as a conductor, or if the conductor were sufficiently robust the compliant material could be removed entirely.

G. Alternative Electrical Interconnection Method

In the presented example wire bonds are used to form electrical connections between the transducer and conductive pads in the carrier. It is possible that alternative approaches could be used to form the electrical connection, the only requirement is that the compliance and impedance of the transducer mount assembly do not exceed the critical limits at the transducers operating frequency (examples of these limits are shown in Table 1). Examples of alternative approaches include flexible electronic circuits where conductive tracts are present on a polymer substrate, conductive adhesives of a sufficiently low modulus, or sprung connections that rely on spring force to form the connection between conductive path, transducer and carrier. All of these mentioned examples operate in a similar principle to the presented wire bond based design, with the primary difference being related to the manufacture of the assemblies.

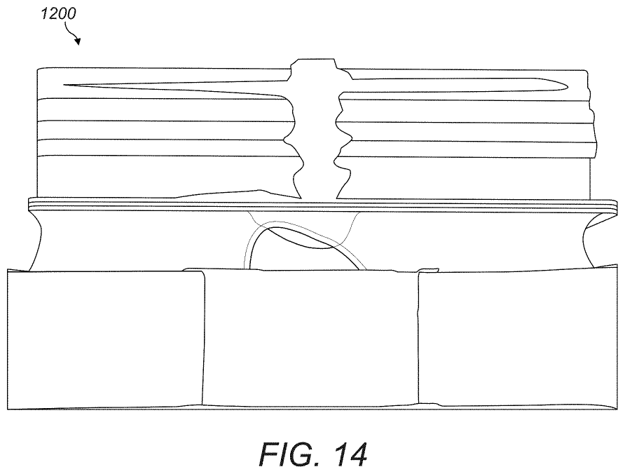

For example, FIG. 14 shows a side view 1200 of a complete package assembly.

### IV. AREAS OF NOVELTY

The design differs from the previously attempted solutions because it allows a transducer to be surface mounted as an individual component in a manner that:
Minimizes mechanical cross-talk to less than or equal to −40 dB
Maximizes the acoustic energy transduction; many of the previously mentioned solutions attenuate acoustic energy in a backing layer. In this design the transducer is decoupled such that minimal energy is lost.
Provides a package outline that allows an individual transducer to be surface mounted using standard manufacturing processes to a substrate layer such as a PCB.
Allows a user to configure the array into any desired geometry and transducer configuration by providing the ultrasonic transducer as an individual component.

This transducer mount design maximizes transduction efficiency, minimizes cross-coupling and allows the mounted transducer to be surface mounted to an array board using standard manufacturing processes.

In addition to the design characteristics and design process, the manufacturing process allows the part to be constructed in an automated manner using pick and place tools. The process is scalable for high volumes and contains a number of novel aspects and inventive steps.
A novel wire bond form that attaches to the transducer using conductive adhesive
Using the wire bonds to support the transducer prior to the silicone curing and set the mount thickness
Provide flexibility to choose whether to wire bond to a transducer or use conductive adhesive based on the temperature resilience of the mounted transducer.
A design and manufacturing process that allows the mount assembly to be produced with pick and place tools.

### V. CONCLUSION

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

Moreover, in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a nonexclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art. The term “coupled” as used herein is defined as connected, although not necessarily directly and not necessarily mechanically. A device or structure that is “configured” in a certain way is configured in at least that way but may also be configured in ways that are not listed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

We claim:

1. An apparatus comprising:
a surface mounted transducer designed such that the design:
Minimizes mechanical cross-talk to less than or equal to −40 dB;
Maximizes the acoustic energy transduction;
Provides a package outline that allows an individual transducer to be surface mounted using standard manufacturing processes to a substrate layer such as a PCB; and
allows a user to configure the array into any desired geometry and transducer configuration by providing the ultrasonic transducer as an individual component.
